(19) United States
(12) Patent Application Publication
(10) Pub. No.: US 2024/0222229 A1
(43) Pub. Date: Jul. 4, 2024

(54) BACK SIDE CONTACTS FOR SEMICONDUCTOR DEVICES

(71) Applicant: International Business Machines Corporation, Armonk, NY (US)

(72) Inventors: Tao Li, Slingerlands, NY (US); Julien Frougier, ALBANY, NY (US); Nicolas Jean Loubet, GUILDERLAND, NY (US); Ruilong Xie, Niskayuna, NY (US)

(21) Appl. No.: 18/091,997

(22) Filed: Dec. 30, 2022

(51) Int. Cl. H01L 23/48; H01L 21/8234; H01L 29/06; H01L 29/417; H01L 29/66; H01L 29/786

(52) U.S. Cl. CPC H01L 23/481; H01L 21/823412; H01L 21/823418; H01L 21/823475; H01L 21/823481; H01L 29/0673; H01L 29/41733; H01L 29/66545; H01L 29/78696

(57) ABSTRACT

Back side and front side contact structures adjoin source/drain regions and facilitate contact spacing in a semiconductor structure. A bottom dielectric isolation layer structure including horizontal and vertical portions is located between the gate regions and a back side interlevel dielectric layer. The vertical portions of the bottom dielectric layer further adjoin the back side contact structure. Source/drain regions of transistors within the semiconductor structure are grown uniformly over semiconductor surfaces. The source/drain regions and the gate regions are protected during back side processing.

### BACKGROUND

The present invention relates generally to the electrical, electronic and computer arts and, more particularly, to FET architectures having back side contacts and methods for forming such contacts.

With shrinking dimensions of various integrated circuit components, transistors such as field-effect transistors (FETs) have experienced dramatic improvements in both performance and power consumption. These improvements may be largely attributed to the reduction in dimensions of components used therein, which in general translate into reduced capacitance, resistance, and increased through-put current from the transistors. Metal oxide semiconductor field-effect transistors (MOSFETs) are well suited for use in high-density integrated circuits. As the size of MOSFETs and other devices decreases, the dimensions of source/drain regions, channel regions, and gate electrodes of the devices, also decrease.

FinFET, nanosheet and vertical transport FETs have been under development for possible use in tight pitch applications. Nanosheet FETs include multiple channel layers, each channel layer being separated by a gate stack including a layer of electrically conductive gate material and a gate dielectric layer. The gate stacks wrap around all sides of the channel layers, thereby forming a gate-all-around (GAA) structure. Epitaxial regions on the ends of the nanosheet channel layers form source/drain regions of the nanosheet FETs.

The use of both front side contacts and back side contacts can facilitate the fabrication and performance of integrated circuits. By providing contacts on both sides of a chip, contact spacing can be greater than if only one side (for example, the front side) includes all contacts for the FETs. Back side power rails can be electrically connected to back side source/drain contacts. The metal gates of the FETs may be exposed during back side processing stages wherein they may be damaged. Bottom dielectric isolation (BDI) layers that are used to protect source/drain regions and metal gates may include pin-holes that compromise their protective functions. More effective protection of the source/drain regions and metal gates of FETs during fabrication of chips having front side and back side contacts would be desirable.

### SUMMARY

In a first aspect of the invention, a monolithic semiconductor structure includes a device layer having a front side and a back side. The device layer includes a front side interlevel dielectric layer and a field-effect transistor within the front side interlevel dielectric layer, the field-effect transistor including a channel region, a gate adjoining the channel region, and first and second source/drain regions extending laterally from the channel region. A back-end-of-line interconnect layer over the front side of the device layer is electrically connected to the device layer. A back side source/drain contact comprising metal directly contacts a bottom surface of the first source/drain region and extends within a back side interlevel dielectric layer. A bottom dielectric isolation layer structure includes a horizontal portion and a pair of vertical portions extending from the horizontal portion, the horizontal portion being between the gate and the back side interlevel dielectric layer, the pair of vertical portions adjoining the back side source/drain contact. The monolithic semiconductor structure may optionally include a front side source/drain contact comprising metal and directly contacting a top surface of the second source/drain region, the front side source/drain contact being electrically connected to the back-end-of-line interconnect layer. A back side interconnect layer over the back side of the device layer is optionally provided, the back side source/drain contact being electrically connected to the back side interconnect layer. The pair of vertical portions of the bottom dielectric isolation layer structure may adjoin the gate and the back side interlevel dielectric layer. Optionally, shallow trench isolation regions are within the back side interlevel dielectric layer and the pair of vertical portions of the bottom dielectric isolation layer structure extend, respectively, between the back side source/drain contact and a pair of the shallow trench isolation regions.

A monolithic semiconductor structure in accordance with a further aspect includes a device layer including a front side and a back side, a front side interlevel dielectric layer, and field-effect transistors within the front side interlevel dielectric layer. Each of the field-effect transistors includes a channel region, a gate adjoining the channel region, and first and second source/drain regions extending laterally from the channel region. A back-end-of-line interconnect layer over the front side of the device layer is electrically connected to the device layer. The monolithic semiconductor structure further includes back side source/drain contacts comprising metal, each back side source/drain contact being in direct contact, respectively, with one of the first and second source/drain regions of the field-effect transistors and extending within the back side interlevel dielectric layer. Bottom dielectric isolation layer structures of the monolithic semiconductor structure include, respectively, horizontal portions and pairs of vertical portions extending, respectively, from each of the horizontal portions. Each of the horizontal portions is between the gate of one of the field-effect transistors and the back side interlevel dielectric layer. Each of the pairs of vertical portions of the bottom dielectric isolation layers adjoins, respectively, one of the back side source/drain contacts. The device layer optionally comprises an integrated circuit. Optionally, the second source/drain regions of a plurality of the field-effect transistors are electrically connected, respectively, to front side source/drain contacts extending within the front side interlevel dielectric layer. Each of the pairs of vertical portions of each bottom dielectric isolation layer structure optionally adjoins the gate of one of the field-effect transistors and the back side interlevel dielectric layer. The monolithic semiconductor structure optionally includes shallow trench isolation regions within the back side interlevel dielectric layer, each pair of vertical portions of each bottom dielectric isolation layer structure extending, respectively, between the back side source/drain contact of one of the field-effect transistors and a pair of the shallow trench isolation regions.

A method of fabricating a monolithic semiconductor structure including a back side contact is provided in accordance with a further aspect of the invention. The method includes obtaining a multi-layer structure including a semiconductor substrate and shallow trench isolation regions extending within the semiconductor substrate. A first bottom dielectric isolation layer extends horizontally over the semiconductor substrate. A second bottom dielectric isolation layer is beneath and extends parallel to the first bottom dielectric isolation layer. A top layer of the semiconductor substrate is positioned between the first bottom dielectric isolation layer and the second bottom dielectric isolation layer. The first bottom dielectric isolation layer includes an opening exposing a top surface portion of the top layer of the semiconductor substrate. The multi-layer structure further includes vertical bottom dielectric isolation layers extending downwardly from the first bottom dielectric isolation layer and the second bottom dielectric isolation layer, each of the vertical bottom dielectric layers adjoining one of the shallow trench isolation regions. Stacks of semiconductor channel layers are arranged in alternating sequence with sacrificial layers, each of the stacks extending vertically from the first bottom dielectric isolation layer. The multi-layer structure further includes a sacrificial semiconductor placeholder extending within the semiconductor substrate and between a pair of the vertical bottom dielectric layers, the sacrificial semiconductor placeholder having an exposed top surface, and a sacrificial gate extending across the stacks. A first source/drain region is grown on first exposed edge portions of the semiconductor channel layers and on the sacrificial semiconductor placeholder. A second source/drain region is grown on second exposed edge portions of the semiconductor channel layers and on the top surface portion of the top layer of the semiconductor substrate. The sacrificial gate is replaced with a metal gate and the sacrificial placeholder is replaced with a back side source/drain contact comprising metal. The method may further include removing the semiconductor substrate, removing the second bottom dielectric isolation layer, forming a back side interlevel dielectric layer over the shallow trench isolation regions, and forming a back side interconnect structure over the back side interlevel dielectric layer.

Techniques and structures as disclosed herein can provide substantial beneficial technical effects. By way of example only and without limitation, one or more embodiments may provide one or more of the following advantages:
Manufacturing and circuit design flexibility;
Benefits of back side power delivery network technology;
Protection of source/drain regions and metal gate during back side processing;
Uniform source/drain growth.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 is a cross-sectional view, of a multi-layer structure formed on a semiconductor wafer;

FIG. 2 is a cross-sectional view showing the multi-layer structure of FIG. 1 following patterning thereof using a hard mask and patterned organic planarization layer;

FIG. 3 is a cross-sectional view thereof following spacer formation and deposition of a fill layer;

FIG. 4 is a cross-sectional view showing the structure depicted in FIG. 3 following further patterning;

FIG. 5 is a cross-sectional view thereof following formation of sacrificial vertical spacers on the multi-layer structure;

FIG. 6 is a cross-sectional view of the structure shown in FIG. 5 following recessing of the vertical spacers and fill layer;

FIG. 7 is a cross-sectional view thereof following further recessing of the fill layer;

FIG. 8A is a cross-sectional view of the structure shown in FIG. 7 following formation of sacrificial gates;

FIG. 8B is a cross-sectional view thereof, taken along a cross section corresponding to the cross-sectional view of FIG. 7;

FIG. 8C is a cross-sectional view thereof taken along a further cross section;

FIG. 9A is a cross-sectional view showing the structure of FIG. 8A following removal of the sacrificial vertical spacers and a layer of the multi-layer structure;

FIG. 9B is a cross-sectional view thereof, taken along the cross section corresponding to the cross section of FIG. 8B;

FIG. 9C is a cross-sectional view thereof, taken along the cross section corresponding to the cross section of FIG. 9C;

FIG. 10A is a cross-sectional view taken along the x cross section of the structure shown in FIG. 10D following spacer formation using the structure shown in FIG. 9A;

FIG. 10B is a cross-sectional view thereof, taken along the Y1 cross section of the structure shown in FIG. 10D;

FIG. 10C is a cross-sectional view thereof, taken along the Y2 cross section of the structure shown in FIG. 10D;

FIG. 10D is a top plan view of the structure shown in FIG. 10A, FIG. 10B and FIG. 10C;

FIG. 11A is a cross-sectional view, taken along the x cross section of FIG. 11D, of the structure shown in FIG. 10A following back side contact patterning;

FIG. 11B is a cross-sectional view thereof taken along the Y1 cross section of FIG. 11D;

FIG. 11C is a cross-sectional view thereof, taken along the Y2 cross section of the structure shown in FIG. 11D;

FIG. 11D is a top plan view of the structure shown in FIG. 11A, FIG. 11B and FIG. 11C;

FIG. 12A is a cross-sectional view, taken along the x cross section of FIG. 12D, of the structure shown in FIG. 11A following formation of a back side contact placeholder;

FIG. 12B is a cross-sectional view thereof taken along the Y1 cross section of FIG. 12D;

FIG. 12C is a cross-sectional view thereof taken along the Y2 cross section of FIG. 12D;

FIG. 12D is a top plan view of the structure shown in FIG. 12A, FIG. 12B and FIG. 12C;

FIG. 13A is a cross-sectional view of the structure shown in FIG. 12A following selective removal of portions of a bottom dielectric isolation (BDI) layer;

FIG. 13B is a cross-sectional view thereof taken along the same cross section as the structure shown in FIG. 12B;

FIG. 13C is a cross-sectional view thereof taken along the same cross section as the structure shown in FIG. 12C;

FIG. 14A is a cross-sectional view of the structure shown in FIG. 13A following formation of source/drain regions;

FIG. 14B is a cross-sectional view of the structure shown in FIG. 14A taken along the same cross section as the structure shown in FIG. 13B;

FIG. 14C is a cross-sectional view of the structure shown in FIG. 14A taken along the same cross section as the structure shown in FIG. 13C;

FIG. 15A is a cross-sectional view, taken along the x cross section of FIG. 15D, of the structure shown in FIG. 14A following multiple steps, including formation of a replacement metal gate;

FIG. 15B is a cross-sectional view thereof taken along the Y1 cross section of FIG. 15D

FIG. 15C is a cross-sectional view thereof taken along the Y2 cross section of FIG. 15D;

FIG. 15D is a top plan view of the structure shown in FIG. 15A, FIG. 15B and FIG. 15C;

FIG. 16A is a cross-sectional view of the structure shown in FIG. 15A following removal of a semiconductor substrate layer;

FIG. 16B is a cross-sectional view thereof taken along the same cross section as FIG. 15B;

FIG. 16C is a cross-sectional view thereof taken along the same cross section as FIG. 15C;

FIG. 17A is a cross-sectional view of the structure shown in FIG. 16A following removal of an etch stop layer and a further portion of the semiconductor substrate;

FIG. 17B is a cross-sectional view thereof taken along the same cross section as FIG. 16B;

FIG. 17C is a cross-sectional view thereof taken along the same cross section as FIG. 16C;

FIG. 18A is a cross-sectional view of the structure shown in FIG. 17A following removal of a bottom dielectric isolation layer;

FIG. 18B is a cross-sectional view thereof taken along the same cross section as FIG. 17B;

FIG. 18C is a cross-sectional view thereof taken along the same cross section as FIG. 17C;

FIG. 19A is a cross-sectional view of the structure shown in FIG. 18A following removal of further semiconductor material from the back side of the structure;

FIG. 19B is a cross-sectional view thereof taken along the same cross section as FIG. 18B;

FIG. 19C is a cross-sectional view thereof taken along the same cross section as FIG. 18C;

FIG. 20A is a cross-sectional view of the structure shown in FIG. 19A following back side formation of a back side interlevel dielectric layer and planarization thereof;

FIG. 20B is a cross-sectional view thereof taken along the same cross section as FIG. 19B;

FIG. 20C is a cross-sectional view thereof taken along the same cross section as FIG. 19C;

FIG. 21A is a cross-sectional view of the structure shown in FIG. 20A following sacrificial placeholder removal;

FIG. 21B is a cross-sectional view thereof taken along the same cross section as FIG. 20B;

FIG. 21C is a cross-sectional view thereof taken along the same cross section as FIG. 20C;

FIG. 22A is a cross-sectional view of the structure shown in FIG. 21A following back side metallization and formation of back side interconnect layers;

FIG. 22B is a cross-sectional view thereof taken along the same cross section as FIG. 21B; and

FIG. 22C is a cross-sectional view thereof taken along the same cross section as FIG. 21C.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of the present invention will be described herein in the context of illustrative embodiments. It is to be appreciated, however, that the specific embodiments and/or methods illustratively shown and described herein are to be considered exemplary as opposed to limiting. Moreover, it will become apparent to those skilled in the art given the teachings herein that numerous modifications can be made to the embodiments shown that are within the scope of the claims. That is, no limitations with respect to the embodiments shown and described herein are intended or should be inferred.

The use of back side contacts in addition to front side contacts may facilitate the manufacture and performance of integrated circuits, particularly those including relatively small elements and increased packing density. Gate-all-around (GAA) transistors such as nanosheet transistors and fin-like field effect transistors (FinFETs) are among the elements employed in high density, high performance applications. Contacts as disclosed herein may be employed in association with either nanosheet or FinFET transistors.

An exemplary sequence of steps that may be employed for the fabrication of integrated circuits including back side contacts is shown in FIG. 1 and subsequent figures. The monolithic structure shown in cross section in FIG. 1 is exemplary and includes a stack of nanosheets including semiconductor channel layers 21 and sacrificial silicon germanium layers 26 formed over a substrate. The nanosheets can, for example, be formed on a bulk semiconductor substrate. Referring to FIG. 1, an exemplary substrate includes a silicon substrate layer 24 and an etch stop layer 28 within the silicon substrate layer 24. The etch stop layer can be, for example, a buried oxide (BOX) layer or a silicon germanium layer. The multi-layer substrate further includes a pair of silicon germanium substrate layers 26′ having relatively high germanium concentrations.

In one or more exemplary embodiments, the semiconductor nanosheet (channel) layers 21 each have a thickness in the range of four to ten nanometers (4-10 nm). The number of semiconductor (channel) layers in the semiconductor layer stack may vary depending on the desired uses and capabilities of the nanosheet transistors to be fabricated. The semiconductor channel layers 21 are essentially monocrystalline silicon layers and are spaced ten to twenty nanometers (10-20 nm) apart in some embodiments. The dimensions of the channel layers and the vertical spacing of channel layers should be considered exemplary as opposed to limiting.

Silicon and silicon germanium layers 21, 26, respectively, can be epitaxially grown on a semiconductor substrate in alternating sequence to obtain a layered stack having the desired number of silicon (channel) layers. The terms “epitaxially growing and/or depositing” and “epitaxially grown and/or deposited” mean the growth of a semiconductor material on a deposition surface of a semiconductor material in which the semiconductor material being grown has the same crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed.

The monolithic structure illustrated in FIG. 1 is obtained by growing silicon and silicon germanium nanosheet layers in alternating sequence on a semiconductor substrate. The sacrificial silicon germanium layers 26, which are replaced by metal gate and gate dielectric materials later in the process, may have a thickness in the range of six to twenty nanometers (6-20 nm). The dimension ranges of the sacrificial silicon germanium layers should also be considered exemplary as opposed to limiting. The sacrificial silicon germanium layers 26 may have the composition Si₁₋ₓGeₓ where x is between 0.2 and 0.3 to allow selective etching with respect to silicon as well as the underlying silicon germanium substrate layers 26′. In one exemplary embodiment, the sacrificial silicon germanium layers 26 and the etch stop layer 28 have the composition Si₁₋ₓGeₓ where x is about 0.3 while the silicon germanium substrate layers 26′ have the composition Si₁₋ₓGeₓ where x is about 0.55. The thicknesses of the silicon germanium substrate layers 26′ may or may not be the same thicknesses as the sacrificial silicon germanium layers 26 that adjoin the silicon channel layers 21.

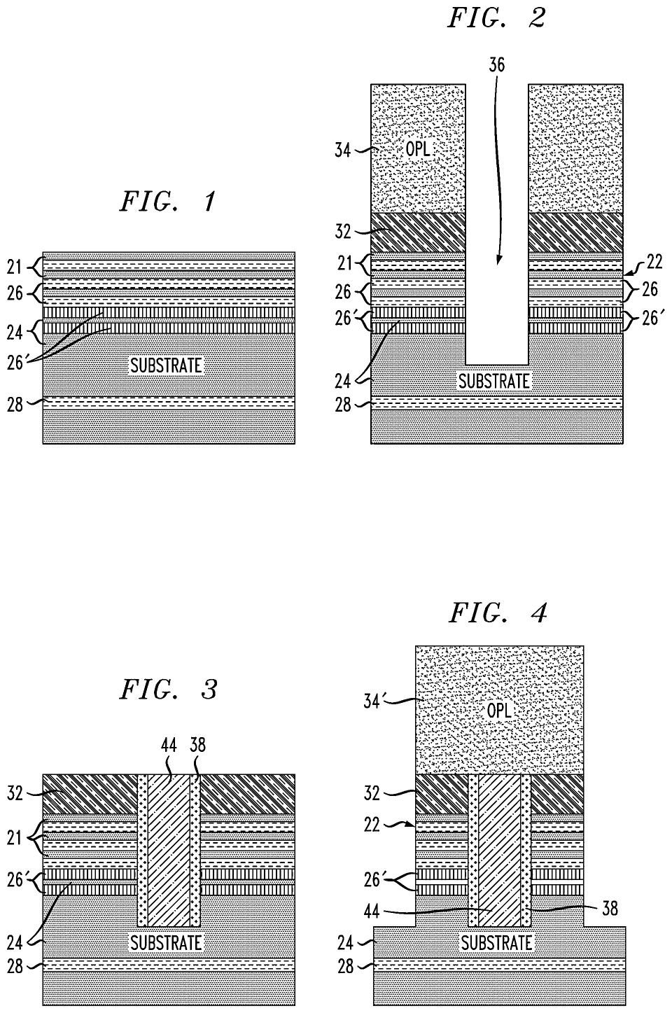

Using a patterned hard mask 32 (for example, silicon nitride) and an organic planarization layer (OPL) 34 for active region patterning, an initial reactive ion etch (RIE) is performed to define NFET to NFET or PFET to PFET space and obtain a multi-layer, finned semiconductor structure. Fin-like nanosheet stacks 22, each including silicon channel layers 21, sacrificial silicon germanium layers 26, silicon germanium substrate layers 26′, and a layer of the semiconductor (e.g. silicon) substrate layer 24 between the silicon germanium substrate layers 26′ extend vertically from the underlying portion of the semiconductor substrate layer 24. The width of each semiconductor channel layer 21 in the top, fin-like portions of an exemplary monolithic structure is fifteen nanometers (15 nm) or greater in some embodiments. As shown in FIG. 2, a trench 36 is formed within the multi-layer substrate described above with respect to FIG. 1 between nanosheet stacks 22. The trench bottom is located above the top surface of the etch stop layer 28. The trench 36 defines the NFET to PFET space, or N2P space. In other words, one side of the trench is intended to include transistors having a first polarity while the other side of the trench will include transistors having a second polarity opposite to the first polarity.

Referring to FIG. 3, the OPL layer 34 is removed by any suitable process (for example, ashing) and vertical spacers 38 are formed on the side walls of the layers adjoining the trench 36. Spacer material can be deposited on the structure shown in FIG. 2 and subsequently etched to form the vertical sidewall spacers 38 shown in FIG. 3. The spacer material forming the sidewalls spacers 38 may include an electrically insulating material such as a nitride, oxynitride, silicon carbon oxynitride, silicon boron oxynitride, or any combination thereof. Standard deposition and etching techniques may be used to form the sidewall spacers 38. For example, spacer material such as silicon nitride can be etched using an anisotropic etch to form the sidewall spacers. The spacer material is removed from all horizontal surfaces of the structure during the etching process, leaving the vertically oriented sidewall spacers 38 on side walls of the hard mask 32 and the semiconductor layers forming the stacks 22. An isolation region is formed within the trench 36 (shown in FIG. 2) to provide electrical isolation of adjoining regions comprising transistors and/or other devices that may be formed on the semiconductor substrate layer 24. A silicon dioxide layer or other suitable dielectric fill may be formed within the trench 36. The oxide fill layer 44 fills the space between the vertical spacers 38 and forms an isolation region. The resulting structure can be planarized to remove excess fill material.

A new OPL layer 34′ is deposited over the hard mask 32 and patterned using lithographic techniques or other suitable processing to define the NFET to PFET space. The widths of the hard mask and the semiconductor stacks 22 are reduced using directional etches. Unprotected portions of the semiconductor substrate layer 24 above the etch stop layer 28 are also partially removed. A structure as shown in cross section in FIG. 4 may accordingly be obtained.

The new OPL layer 34′ is removed and sacrificial, vertically extending spacers 46 are formed on the exposed side walls of the semiconductor stacks, the hard mask 32, and the semiconductor substrate layer 24. If the sacrificial spacers 46 are silicon germanium spacers, the sacrificial spacers should have a relatively high germanium content, for example Si₁₋ₓGeₓ where x is about 0.55. The sacrificial spacers 46 may alternatively comprise materials such as TiOₓ or AlOₓ. An oxide fill layer 48 is deposited on the resulting structure. FIG. 5 illustrates an exemplary structure 50 that may be obtained.

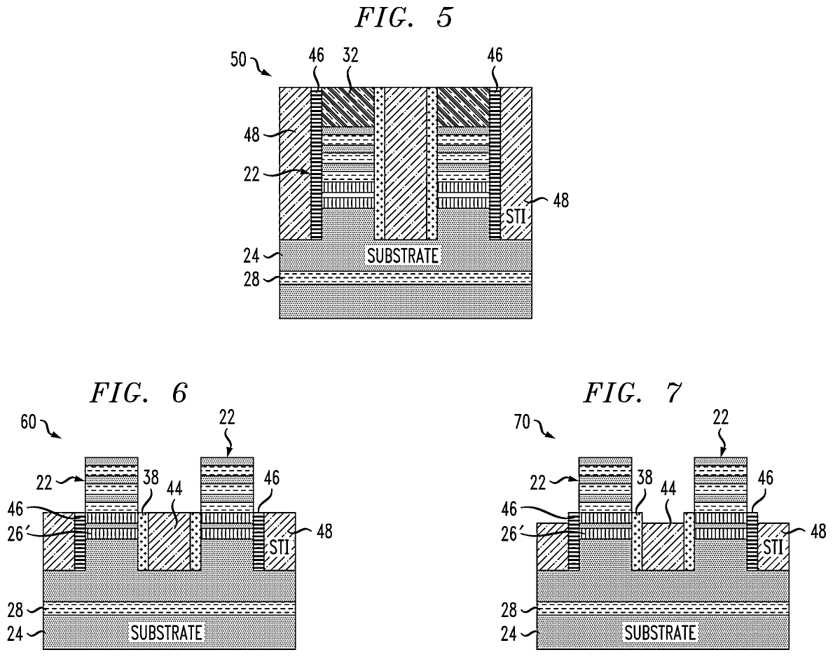

The hard mask 32 is removed and the oxide fill layers 48, 44 recessed to expose portions of the vertical spacers 46, 38 lining the stacks 22 of semiconductor layers 21, 26. The bottom portions of the vertical spacers 46, 38 lining the semiconductor substrate layer 24 and silicon germanium substrate layers 26′ remain protected by the remaining portions of the fill layers 48, 44. The exposed portions of the vertical spacers 46, 38 are removed, thereby obtaining a structure 60 as schematically illustrated in FIG. 6. The oxide fill layers are optionally further recessed with respect to the vertical spacers 46, 38 and form shallow trench isolation (STI) regions that electrically isolate portions of the structure. FIG. 7 illustrates an exemplary structure 70 following such optional recessing.

A sacrificial gate layer is formed over the stacks 22 of nanosheet layers. The sacrificial gate layer may comprise, for example, a thin layer of SiO₂ and amorphous silicon (a-Si) or polycrystalline silicon (polysilicon). Sacrificial gate material used to form the sacrificial gate layer may be formed using, for example, physical vapor deposition (PVD), chemical vapor deposition (CVD), plasma enhanced chemical vapor deposition (PECVD), inductively coupled plasma chemical vapor deposition (ICP CVD), or any combination thereof. A hard mask (for example, SiNx or a combination of SiNx and SiO₂) 52 is deposited and patterned on the top surface of the sacrificial gate layer. The sacrificial gate layer is then subjected to a reactive ion etch. The resulting structure 80 includes sacrificial gates 54 that extend perpendicularly with respect to the parallel nanosheet stacks 22. The gate hard mask 52 adjoins the top surfaces of the sacrificial gates. The sacrificial gates 54 extend through both nFET and pFET regions in one or more embodiments of the exemplary structure.

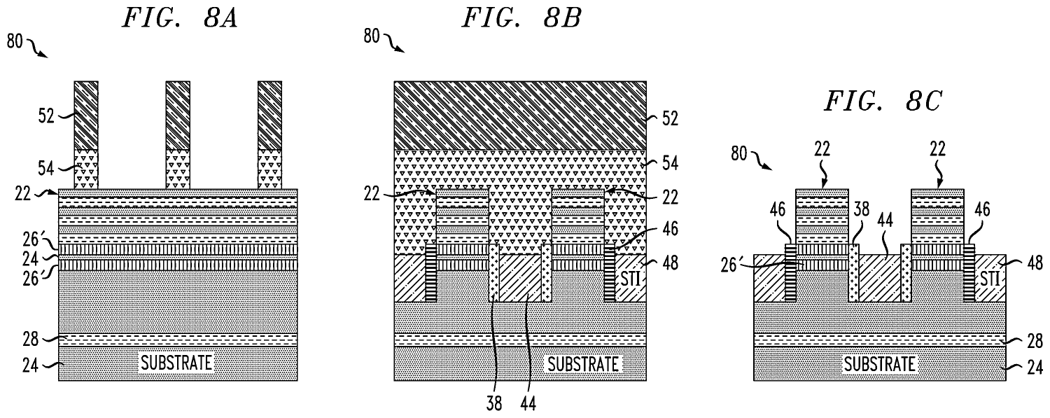

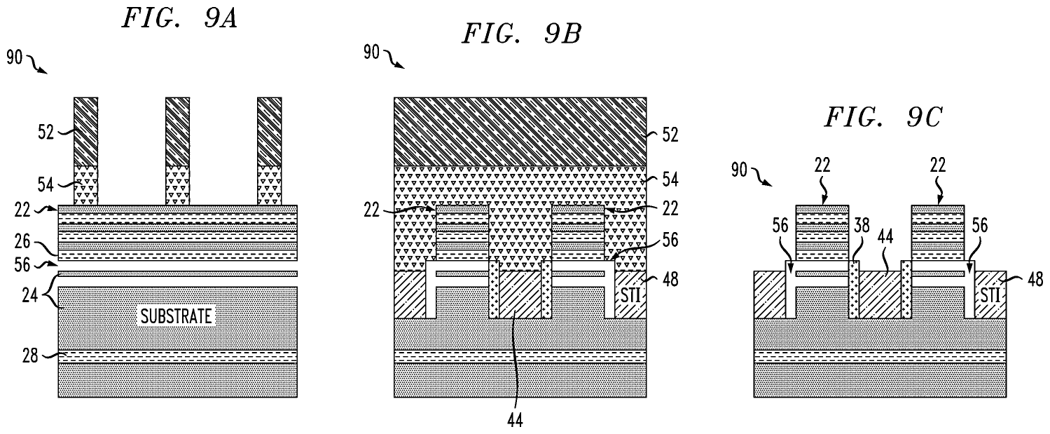

The top substrate layers 26′ and the sacrificial spacers 46 are selectively removed from the structure 80 shown in FIG. 8A, FIG. 8B and FIG. 8C, thereby forming spaces 56 between the semiconductor substrate layer 24 and the nanosheet stacks 22 and between portions of the semiconductor substrate layer and the oxide fill (STI) regions 48. As discussed above, the top substrate layers 26′ have a higher germanium content than the sacrificial silicon germanium layers 26 within the nanosheet stacks 22 and can therefore be etched selectively with respect to such layers. A selective etching process such as dry HCl etch can be employed to remove the top substrate layers 26′ and the sacrificial spacers selective to the silicon channel layers 21 as well as the sacrificial silicon germanium layers 26. FIG. 9A, FIG. 9B and FIG. 9C provide sectional views in various cross sections, respectively, of the resulting structure 90.

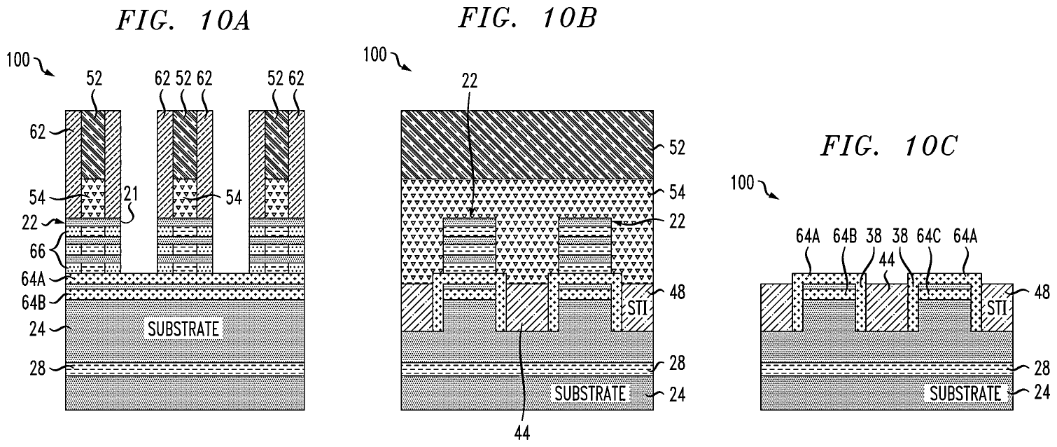

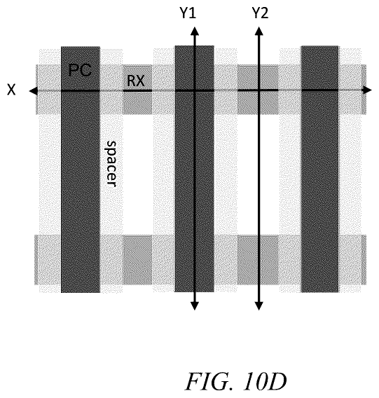

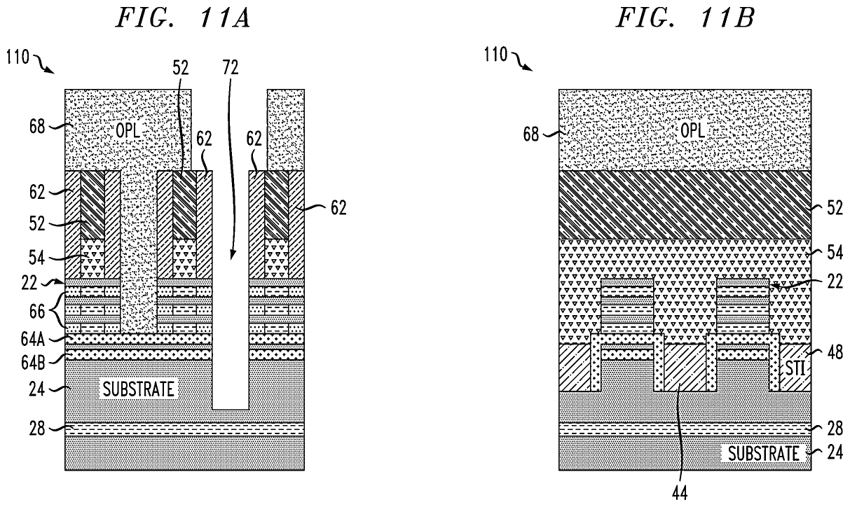

A dielectric layer is deposited over the resulting structure and fills the spaces 56 beneath the nanosheet stacks 22 and also between sidewall portions of the semiconductor substrate layer 24 and the STI (shallow trench isolation) regions formed by the oxide fill layers. Dielectric spacers layers formed in the spaces 56 and adjoining the sacrificial gates 54 may comprise, for example, SiN, SiBCN, SiOCN and/or SiCO, or other suitable dielectric materials. Such materials can be deposited using ALD (atomic layer deposition). In an exemplary embodiment, silicon nitride is formed on the monolithic structure. The silicon nitride layer is selectively etched back to remove unprotected horizontal portions thereof, thereby forming vertical, top sidewall gate spacers 62 on the sidewalls of the sacrificial gates 54. The spacer material beneath the nanosheet stacks 22 is protected and remains within the spaces 56 following etch-back, thereby forming first and second bottom dielectric isolation layers 64A, 64B. The portions of the spaces 56 previously occupied by the sacrificial spacers 46 are replaced by vertically extending isolation layers 64C. FIG. 10B and FIG. 10C provide sectional views of a resulting structure including the horizontal, bottom dielectric isolation layers 64A, 64B beneath the nanosheet stacks 22 and the vertical isolation layers 64C. FIG. 10A and FIG. 10D provide sectional and top plan views, respectively, that schematically illustrate the gate spacers 62. (It will be appreciated that the sectional views provided in FIG. 1 through FIG. 7, FIG. 8B and FIG. 9B were taken along the Y1 cross sectional plane as identified in FIG. 10D.)

Referring to FIG. 10A and FIG. 10C, the portions of the nanosheet stacks 22 outside the regions protected by the sacrificial gate 54, hard mask 52 and gate spacers 62 are subjected to a reactive ion etch down to the upper bottom dielectric isolation (BDI) layer 64A. The resulting structure is subjected to a timed wet etching process to selectively recess the silicon germanium layers 26 within the nanosheet stacks 22. Hydrogen chloride gas is employed in some embodiments to selectively remove silicon germanium, leaving the silicon nanosheet (channel) layers 21 substantially intact. Alternatively, a wet etch process containing ammonia and hydroperoxide can be used to etch SiGe selective to other materials. Each exposed end of the silicon germanium layers 26 may be recessed by, for example, three to seven nanometers (3-7 nm). The silicon germanium layers 26 have smaller widths than the widths of the silicon (channel) layers 21 following the timed etch. The stack of semiconductor nanosheet layers accordingly includes indents between the end portions of each pair of silicon (channel) layers 21.

Dielectric spacer material is deposited in the trenches resulting from the reactive ion etch of the stacks of semiconductor nanosheet layers. The dielectric spacer material is etched back to form inner spacers 66 within each of the indents in the stacks of nanosheet semiconductor layers. A selective wet etch may be employed to remove the dielectric inner spacer material outside of the indents between silicon layers. A structure 100 as schematically illustrated in FIG. 10A, FIG. 10B, FIG. 10C and FIG. 10D may be obtained. The inner spacers 66 of the structure 100, as shown in FIG. 10A, may comprise, for example, low-k dielectric material. Silicon oxynitride, SiBCN (silicon borocarbonitride), SiOCN (silicon oxycarbonitride), and/or SiOC (silicon oxycarbide) inner spacers may be formed in some embodiments. Relatively low-k silicon nitride-based materials, if used to form the inner spacers, can be selectively etched using, for example, phosphoric acid. Various techniques of forming inner spacers for nanosheet transistors have been discussed in the literature and may continue to be developed. The particular materials and steps discussed with respect to inner spacer formation should accordingly be considered exemplary as opposed to limiting.

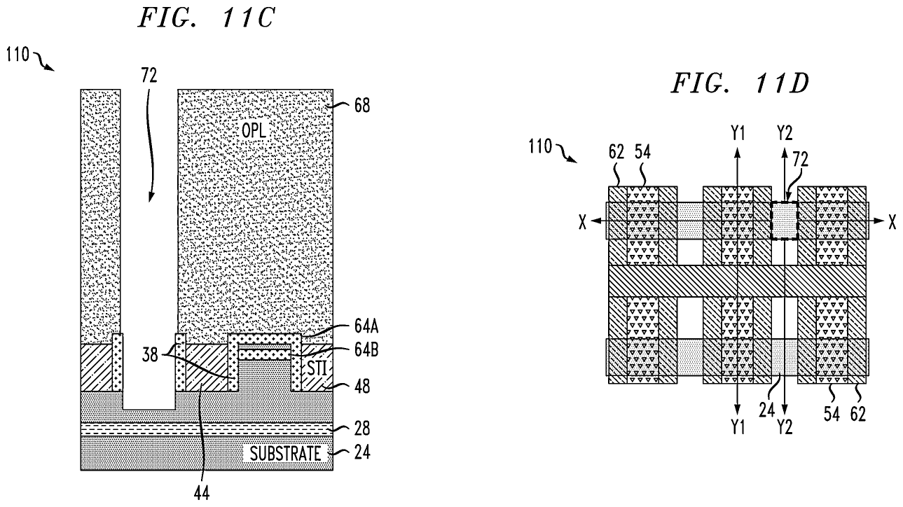

An organic planarization layer (OPL) 68 is deposited and then patterned in forming a structure 110 as illustrated in FIG. 11A, FIG. 11B, FIG. 11C and FIG. 11D using the structure 100 described above. A lithographically patterned hard mask (not shown) may be employed to form vertical placeholder trenches 72 extending through the OPL 68 and partially within the substrate layer 24. As shown in FIG. 11C, each trench 72 extends between a pair of vertically extending isolation layers (spacer 38, isolation layer 64C), each of which lines an oxide fill layer 44, 48. The bottom of each trench 72 is at or above the etch stop layer 28.

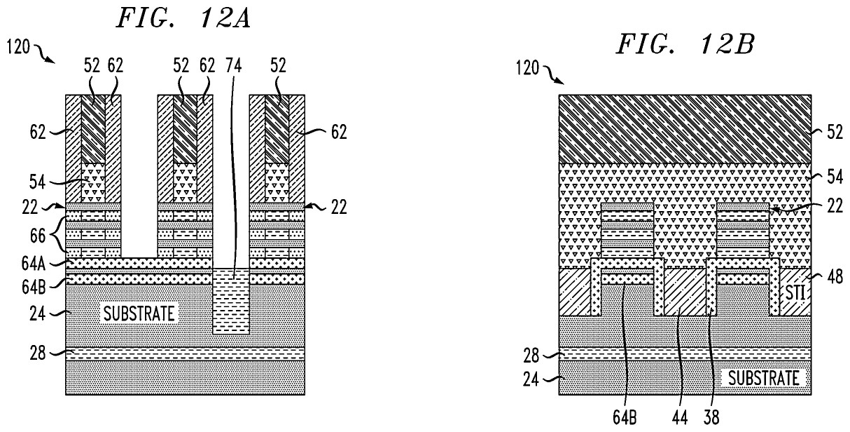

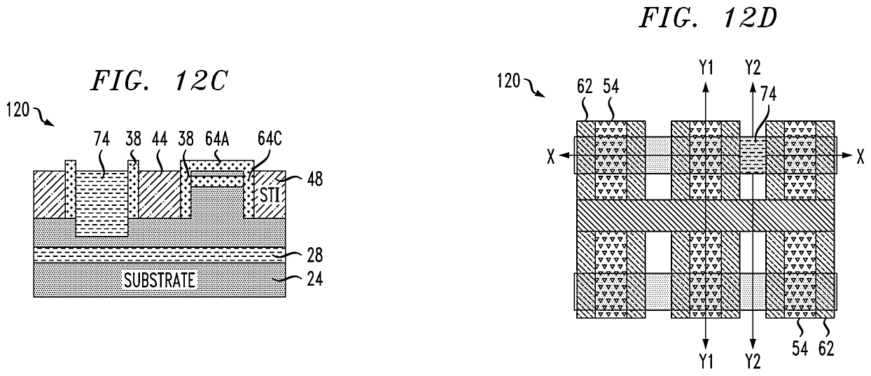

A back side contact placeholder material layer is grown or deposited in the placeholder trenches 72. The placeholder material layer comprises sacrificial placeholders 74 within the substrate that are later replaced by metal back side contacts, as described below. The top surfaces of the sacrificial placeholders may extend above the bottom surface of the bottom BDI layer 64B but below the levels of the top BDI layer 64A and the nanosheet stacks 22. In one exemplary embodiment, the sacrificial placeholders 74 are epitaxially grown on the exposed surfaces of the semiconductor substrate 24. Silicon germanium placeholders may, for example, be grown from the bottoms of the placeholder trenches to desired heights therein. FIG. 12A, FIG. 12B, FIG. 12C and FIG. 12D illustrate an exemplary structure 120 that may be obtained following sacrificial placeholder growth.

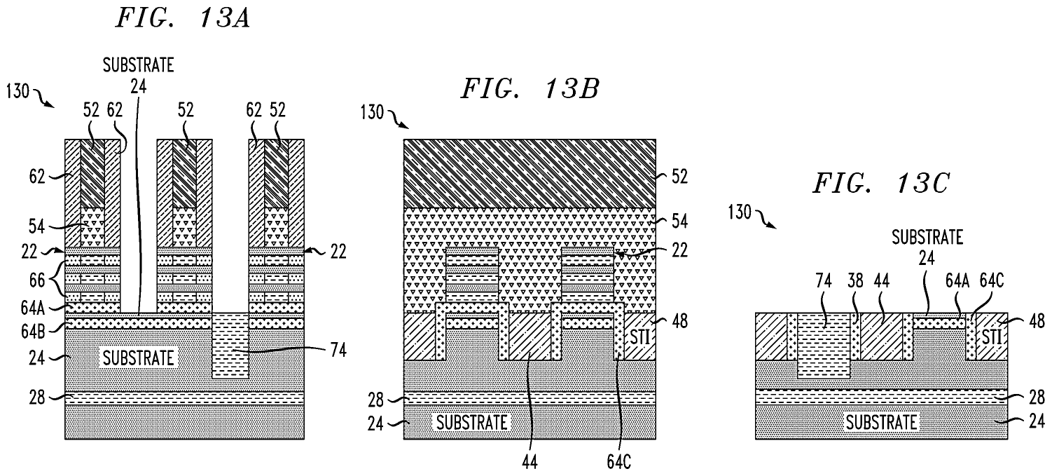

The top BDI layer 64A is selectively removed from regions of the structure 120 in which source/drain regions are later grown. As shown in FIG. 13A and FIG. 13C, the top surface of the semiconductor substrate 24 is exposed following such removal. A structure 130 is obtained in which a top surface of a semiconductor layer (e.g. silicon and silicon germanium) is exposed on both sides of the nanosheet stacks 22, as shown in the cross-sectional view provided in FIG. 13A.

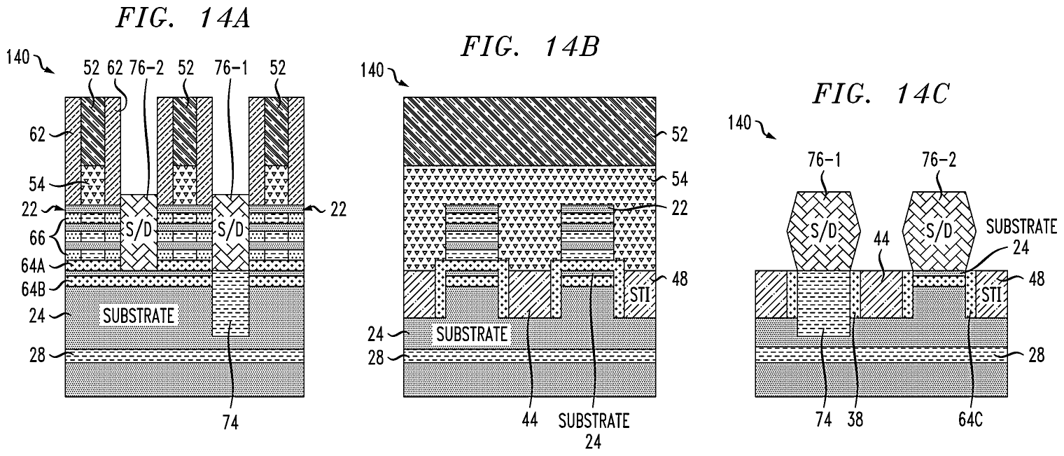

Source/drain regions 76-1, 76-2 are epitaxially grown on the exposed edges of the silicon nanosheet channel layers 21. Selected source/drain regions 76-1 are grown directly on sacrificial placeholders 74 as well as on the edges of the channel layers 21. Other source/drain regions 76-2 are grown on channel edge portions as well as the portions of the substrate layer 24 exposed upon removal of portions of the top BDI layer 64A as discussed above. As shown in the exemplary structure 140 depicted in FIG. 14A and FIG. 14C, epitaxial growth of the source/drain regions 76-1, 76-2 is timed to control height and width dimensions. The prior removal of portions of the top BDI layer 64A facilitates epitaxial growth uniformity as both source/drain regions are grown over semiconductor surfaces instead of just one such region in embodiments wherein the top BDI layer 64A remains intact.

Dopants may be incorporated within the source/drain regions in situ using appropriate precursors, as known in the art. By “in-situ” it is meant that the dopant that dictates the conductivity type of a doped layer is introduced during the process step, for example epitaxial deposition, that forms the doped layer. As used herein, the term “conductivity type” denotes a dopant region being p-type or n-type. As used herein, “p-type” refers to the addition of impurities to an intrinsic semiconductor that creates deficiencies of valence electrons. In a silicon-containing substrate, examples of p-type dopants, i.e., impurities include but are not limited to: boron, aluminum, gallium and indium. As used herein, “n-type” refers to the addition of impurities that contribute free electrons to an intrinsic semiconductor. In a silicon-containing substrate, examples of n-type dopants, i.e., impurities, include but are not limited to antimony, arsenic and phosphorous. Exemplary epitaxial growth processes that are suitable for use in forming silicon and/or silicon germanium epitaxy include rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). An nFET region(s) includes transistors having n-type source/drain regions while the pFET region(s) includes p-type source/drain regions. In one or more embodiments, both nFET and pFET regions are formed on the semiconductor substrate 24. Source/drain regions of nanosheet devices are typically grown prior to the RMG (replacement metal gate) process.

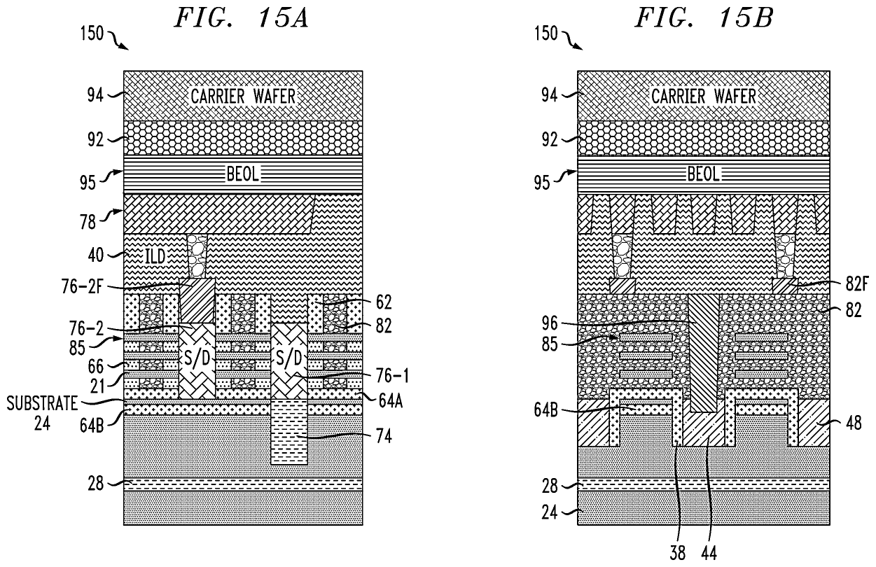

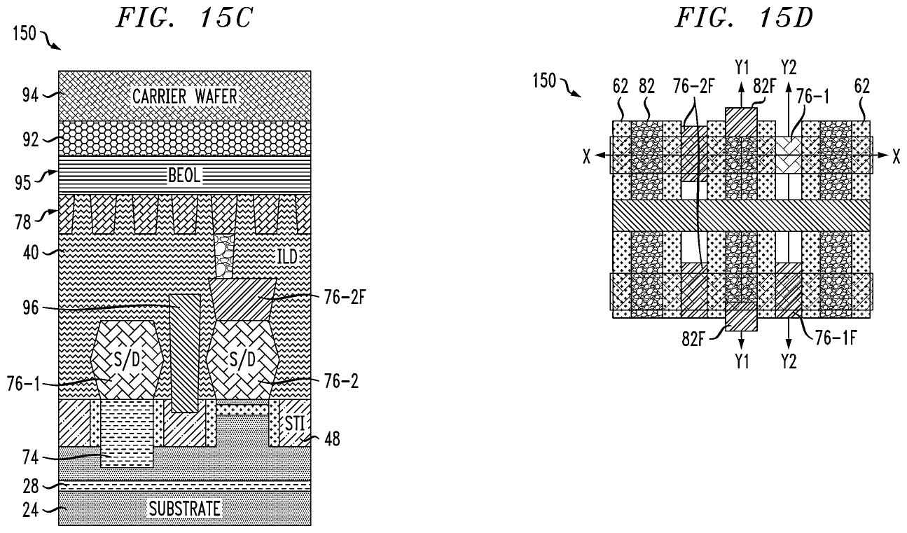

FIG. 15A, FIG. 15B, FIG. 15C and FIG. 15D provide views of an exemplary structure 150 obtained following ILD deposition, CMP, sacrificial gate and hard mask removal, release of silicon germanium nanosheet layers, replacement gate formation, gate cut formation, middle-of-line (MOL) contact formation, back-end-of-line (BEOL) formation, and carrier wafer bonding. Process steps for effecting gate replacement, metal contact formation and formation of metal interconnect layers are known to the art and shall accordingly be described briefly below. It will be appreciated that nanosheet transistor formation and the formation of other elements may continue to be developed. The processing steps described for obtaining the structure 150 should accordingly be considered exemplary and not limiting.

An interlevel dielectric (ILD) layer 40 may be deposited over the structure using deposition techniques including, but not necessarily limited to, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD), spin-on coating, sputtering, and/or plating. The front side ILD layer 40 may include, but is not necessarily limited to, low-k materials (e.g., k less than about 4.0), such as, for example, porous silicates, carbon doped oxides, silicon dioxides, silicon oxynitrides, carbon-doped silicon oxide (SiCOH) and porous variants thereof, silsesquioxanes, siloxanes, or other dielectric materials having, for example, a dielectric constant in the range of about 2 to about 4. An SiCOH dielectric film having a dielectric constant (k) of about 2.7-2.8 can, for example, comprise one or more ILD layers. Such a dielectric film can be deposited using PECVD. ILD layers may, in some embodiments, comprise an ultra low-k (ULK) dielectric material having a dielectric constant of 2.5 or below. The ILD layer comprises multiple layers in some embodiments. The ILD layer 40 fills the spaces between the gate spacers 62 and extends down to the top surfaces of the STI regions 48, 44.

The front side ILD layer 40 is planarized down to the top surfaces of the hard mask 52. The hard mask 52 and sacrificial gate layer 54 are removed from the resulting structure. The silicon germanium layers 26 are then selectively removed, leaving stacks of silicon (channel) layers 21 separated by spaces (not shown). Hydrogen chloride gas is employed in some embodiments to selectively remove silicon germanium, leaving silicon nanosheets substantially intact. Alternatively, a wet etch process containing ammonia and hydroperoxide can be used to etch SiGe selective to other materials. Gate stacks 82 are formed in adjoining relation to the nanosheet (channel) layers 21. A gate dielectric layer forms portions of the gate stacks that replace the sacrificial silicon germanium nanosheet layers. The gate stacks adjoin the silicon nanosheet channel layers 21, forming a gate-all-around structure. Non-limiting examples of suitable materials for the gate dielectric layer include oxides, nitrides, oxynitrides, silicates (e.g., metal silicates), aluminates, titanates, nitrides, or any combination thereof. Examples of high-k gate dielectric materials (with a dielectric constant greater than 7.0) include, but are not limited to, metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k material may further include dopants such as, for example, lanthanum and aluminum. The gate dielectric layer may be formed by suitable deposition processes, for example, chemical vapor deposition (CVD), plasma-enhanced chemical vapor deposition (PECVD), atomic layer deposition (ALD), evaporation, physical vapor deposition (PVD), chemical solution deposition, or other like processes. The thickness of the gate dielectric material may vary depending on the deposition process as well as the composition and number of high-k dielectric materials used. In one exemplary embodiment, a high-k dielectric layer having a thickness of 2.5 nm is employed. In some embodiments, the gate dielectric layer includes multiple dielectric layers.

Electrically conductive gate material is deposited in the spaces formerly filled by the sacrificial gate 54 and the silicon germanium nanosheet layers 26. The deposited metal gate material forms the metal gate of the nanosheet field-effect transistors of the resulting structure 150. In some embodiments, the electrically conductive gate includes a work function metal (WFM) layer. WFM serves dual purposes: Vt setting and gate conductor. Non-limiting examples of suitable work function metals include p-type work function metal materials and n-type work function metal materials. P-type work function materials include compositions such as ruthenium, palladium, platinum, cobalt, nickel, and conductive metal oxides, titanium nitride, or any combination thereof. N-type metal materials include, for example, hafnium, zirconium, titanium, tantalum, aluminum, metal carbides (e.g., hafnium carbide, zirconium carbide, titanium carbide, and aluminum carbide), aluminides, or any combination thereof. The work function metal(s) may be deposited by a suitable deposition process, for example, a conformal ALD process.

In one exemplary embodiment, an n-type WFM layer having a thickness of three nanometers (3 nm) may be formed on the gate dielectric layer. The thickness of the WFM layer may, for example, be in the range of two to ten nanometers (2-10 nm), with thinner layers being used as device scaling decreases. The n-type WFM layer is intended for use in association with the n-type transistors. Portions of the n-type WFM layer that may also be deposited in the pFET region may accordingly be replaced later in the process. The n-type WFM layer and the gate dielectric may fill the spaces between the silicon channel layers 21 and the regions formerly occupied by the sacrificial gates 54.

The n-type WFM layer in the nFET region may be protected by a patterned OPL (not shown). Exposed portions of the n-type WFM layer in the pFET region are removed, leaving open spaces between the silicon channel layers 21 within the pFET region. Gate metal is accordingly removed from the pFET region while the protected nFET region remains intact. An SC1 etch or other suitable etch processes can be employed to selectively remove gate metal while leaving the gate dielectric layer substantially intact. The duration of the etch, which is sufficient to allow removal of all gate metal from the pFET region, does not affect the gate metal in the nFET region. Following removal of the originally deposited n-type WFM layer from the pFET region, new gate metal deemed appropriate for the pFET transistors is deposited. A p-type WFM layer is deposited in embodiments wherein the first-deposited metal is n-type. It will be appreciated that the process can be reversed and n-type metal can be deposited subsequent to p-type metal in some alternative embodiments. Metal overburden can be removed using chemical mechanical planarization. An FEOL (device) layer 85 comprising FETs and possibly other electronic devices (not shown) within an ILD layer 40 is accordingly provided.

Silicon-based devices typically include multiple interconnect metallization layers above a device (front-end-of-line/FEOL) layer 85 that contains field-effect transistors (FETs) and/or other electronic structures. FEOL processing includes high-temperature steps for manipulating semiconductor conductivity. Middle-of-line (MOL) processing includes steps typically used for fabricating metal contacts for logic circuitry components such as field-effect transistors (FETs), resistors, diodes, and capacitors. MOL processing may include intermediate-temperature steps for forming semiconductor-metal compounds (for example, silicides, germanosilicides) for electrical contacts. Back-end-of-line (BEOL) processing involves the creation of metal interconnecting wires that connect the devices formed in FEOL processing to form electrical circuits and may include silicidation as discussed above with respect to MOL processing.

A MOL ILD layer is deposited over the device layer and patterned. The same reference numeral (40) is employed to identify the previously deposited ILD layer as well as the MOL ILD layer deposited thereon. Openings within the MOL ILD layer extend down to the top surfaces of selected source/drain regions. Top (front side) source/drain contacts 76-2F can comprise electrically conductive material including, but not limited to, a silicide layer such as Ti, Ni, NiPt, and a metal adhesion layer, such as TiN, TaN and conductive metal fills, such as tungsten (W), aluminum (Al), copper (Cu), cobalt (Co), ruthenium (Ru), molybdenum (Mo), or any other suitable conductive material, and combinations thereof. A metal silicide layer can be formed on the source/drain regions 76-2 by depositing a metal liner such as a titanium liner thereon prior to deposition of the metal fill layers. Such a titanium liner can be deposited using physical vapor deposition (PVD), and is followed by annealing at a temperature between about two hundred and eight hundred degrees Centigrade to form the metal silicide. The structure may be annealed to form a metal silicide layer between the contact metal and the source/drain epitaxy. The front source/drain sidewall contacts 76-2F are incorporated within the device layer 85. Each front source/drain contact 76-2F forms an electrical connection to one of the source/drain regions 76-2. Gate contacts 82F are also formed on the front side of the device layer. The gate contacts and the front source/drain contacts may or may not be formed at the same time and may or may not comprise the same electrically conductive material(s).

Metal interconnecting wires that connect the devices in the FEOL (device) layer 85, thereby forming electrical circuits, are formed within one or more BEOL layers 95 following MOL processing. The BEOL layers are formed over the front side of the device layer 85. The metal lines including the interconnecting wires in the BEOL layers are deposited in sequence (e.g. M1, M2, M3, etc.) over the FEOL layer 85 and include dielectric layers. The interconnecting wires within each metal line are electrically connected to interconnecting wires in other metal lines and to the devices in the FEOL (device) layer 85. BEOL processing typically includes low-temperature steps for forming metal wires and preserving temperature sensitive FEOL and MOL structures. BEOL processing involves the formation of interconnect layers above the MOL layer(s). A chip may have multiple BEOL interconnect layers. Each interconnect layer, which has a wiring scheme, is connected to another interconnect layer by vias. The wires and vias are within dielectric layers, one or more of which may comprise low-k material. The MOL layer may including wiring 78 for electrically connecting the front side contacts with the adjoining BEOL layer.

A carrier wafer 94 is bonded to the resulting structure above the BEOL layer(s) 95. A bonding oxide layer may be deposited on each of the top BEOL layer and the carrier wafer. The carrier wafer is bonded to the BEOL layers by the bonding oxide layers and form the bonding oxide layer 92. An exemplary monolithic semiconductor structure 150 shown in FIG. 15A, FIG. 15B, FIG. 15C and FIG. 15D includes an FEOL (device) layer 85 comprising nFET and pFET transistors, optionally other electronic devices, and an MOL layer comprising front side contacts 76-1F (shown in FIG. 15D), 76-2F, 82F, and BEOL layer(s) 95 electrically connected to the devices in the device layer. Some of the source/drain regions are not associated with front side contacts, as shown in FIG. 15A, FIG. 15C and FIG. 15D. The structure 150 further includes a carrier wafer 94. The contacts electrically connect selected source/drain regions 76-1 and/or 76-2 to the BEOL layer 95. A gate cut region 96 comprising dielectric material electrically isolates an nFET region of the structure from a pFET region thereof in some exemplary embodiments.

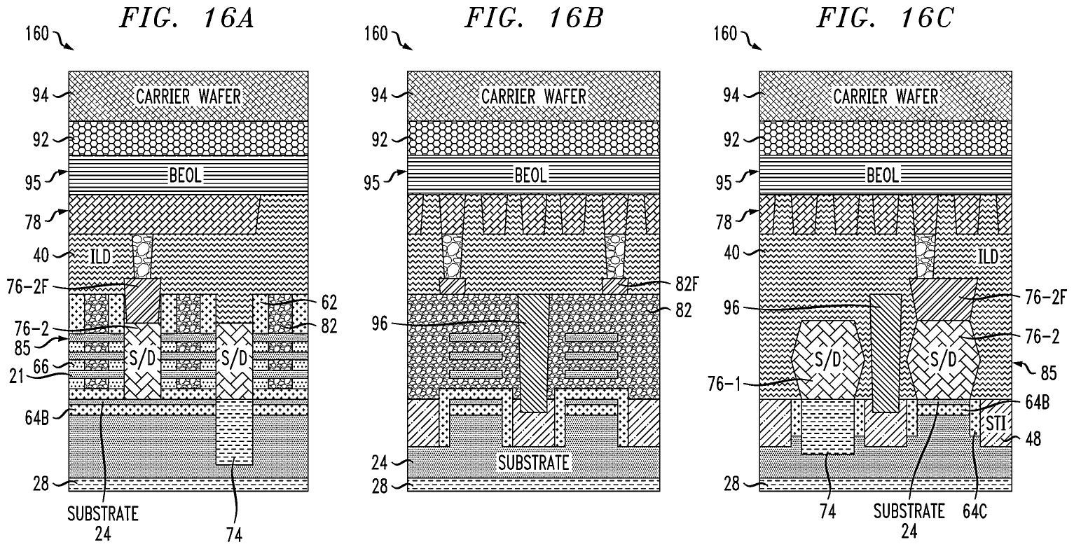

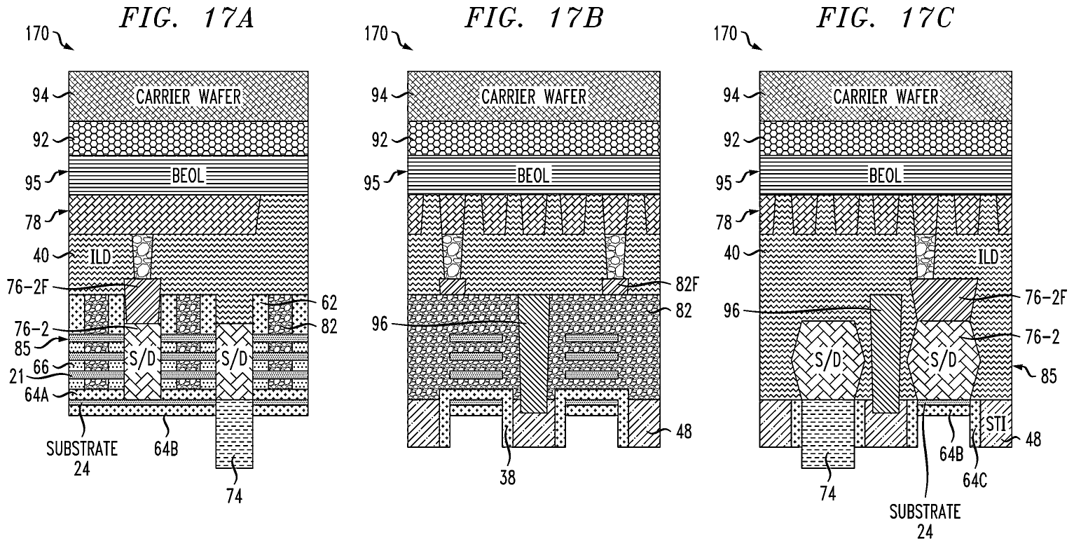

The monolithic semiconductor structure 150 is flipped and the portion of the silicon substrate layer 24 beneath the etch stop layer 28 is removed therefrom. A substrate grinding, chemical mechanical polishing (CMP) and selective wet process may be performed at this stage of the process. Ammonium hydroxide (NH₄OH) or tetramethylammonium hydroxide (TMAH) may be employed for wet process as their selectivity to silicon germanium is high. (As indicated above, the etch stop layer may comprise silicon germanium.) A monolithic structure 160, as schematically illustrated (shown front side up) in the X, Y-1 and Y-2 cross-sectional views of FIG. 16A, FIG. 16B and FIG. 16C may be obtained. The etch stop layer 28 and the portion of the silicon substrate layer 24 beneath the bottom BDI layer 64B are then selectively removed, thereby obtaining a structure 170 (also shown front side up) as illustrated in FIG. 17A, FIG. 17B and FIG. 17C. The sacrificial placeholders 74 are exposed on the back side of the monolithic structure 170 following such removal. The top and bottom BDI layers 64A, 64B protect the metal gate and source/drain regions during this stage of the process. As the top BDI layer 64A may contain pin-holes generated during FEOL processing, the multi-layer protection of the gate and source/drain regions can be beneficial. The vertical BDI layers 38, 64C provide additional protection for the metal gate regions at this stage as well as later stages of the fabrication process.

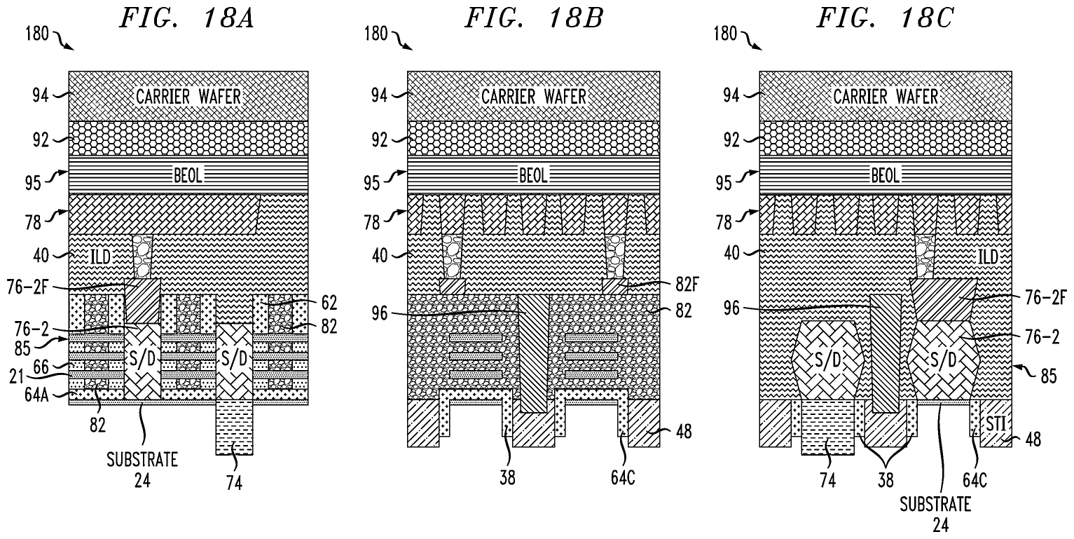

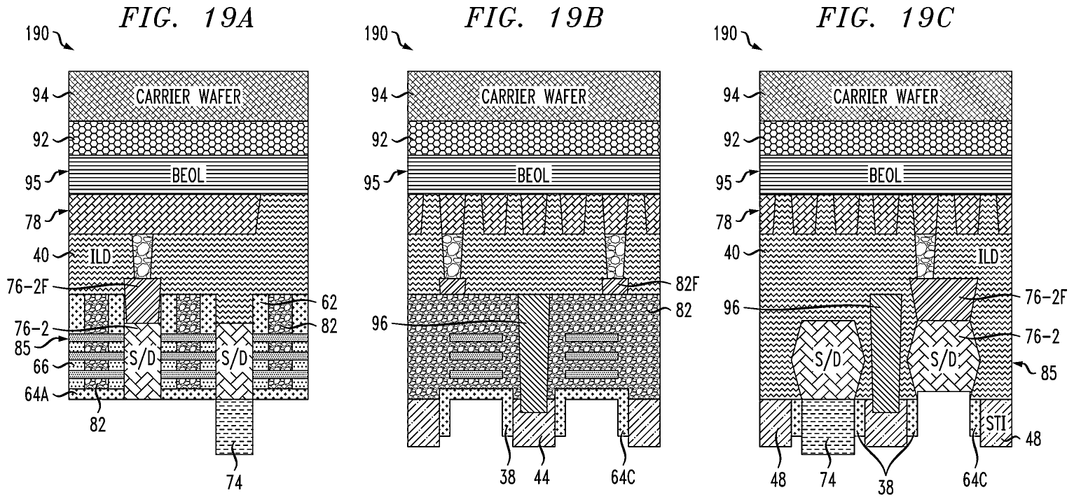

The bottom BDI layer 64B is removed from the structure to obtain a monolithic structure 180 as illustrated in FIG. 18A, FIG. 18B and FIG. 18C. The remaining portion of the silicon substrate layer 24 is then removed. An anisotropic etch may be used to remove this remaining silicon layer, which is a thin layer less than five nanometers (5 nm) in thickness in some exemplary embodiments. Slight etch-back of the sacrificial placeholder 74 and the exposed source/drain region 76-1 may occur during removal of the remaining silicon. A monolithic structure 190 as shown in FIG. 19A, FIG. 19B and FIG. 19C may be obtained. The monolithic structure includes portions of the horizontally extending top BDI layer 64A. It further includes vertically extending BDI layers comprised of elements 38 and 64C discussed above. The top BDI layer 64A adjoins the bottom surface of the gate stack 82 as shown in FIG. 19B. Vertically extending BDI layers 38, 64C adjoin the horizontal BDI layer 64A, the metal gate layer, and STI regions 48. The spacers 38 are also functional as BDI layers and adjoin the top BDI layer 64A, the metal gate layer, and the oxide layer 44 as shown in FIG. 19B. As viewed in the cross-sectional view through the source/drain regions 76-1, 76-2 illustrated in FIG. 19C, the vertically extending BDI layers adjoin side wall surfaces of the sacrificial placeholder 74.

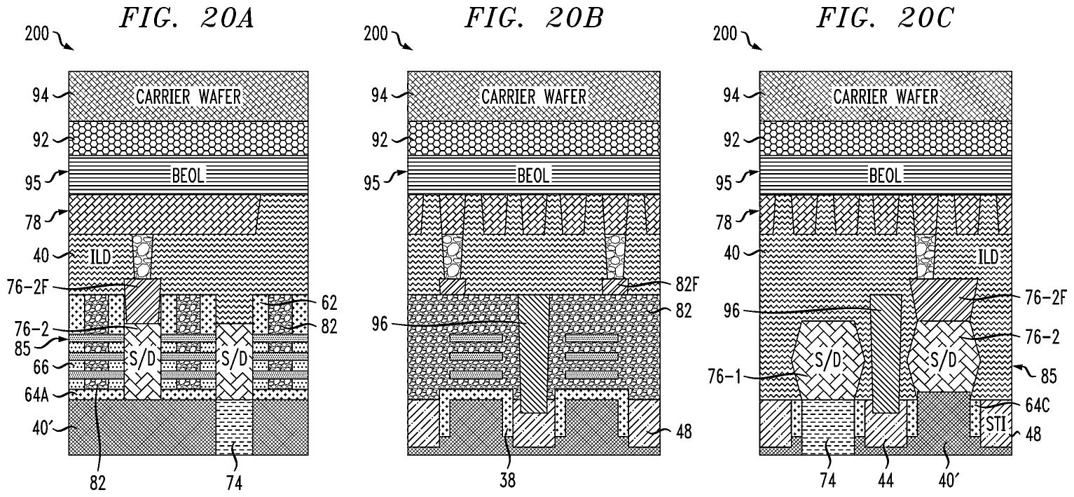

A back side ILD layer 40′ is deposited on the inverted structure 190 and planarized down to the back side surfaces of the sacrificial placeholders 74. The back side surfaces of the sacrificial placeholders are top-facing during such processing. Though not required, the back side ILD layer 40′ may have the same composition(s) as the previously formed ILD layer 40 discussed above. The back side surfaces of the sacrificial placeholders 74 are exposed in the resulting structure 200, as shown in FIG. 20A and FIG. 20C.

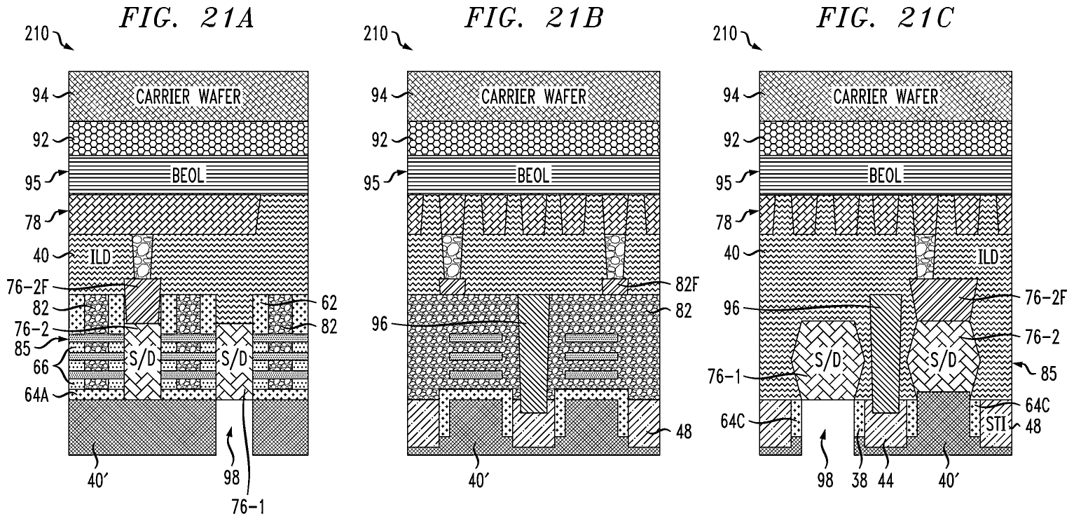

The sacrificial placeholders 74 are selectively removed using conventional dry etch or wet etch processes. Cavities 98 replacing the sacrificial placeholders 74 are formed in the back side ILD layer 40′, as shown in FIG. 21A and FIG. 21C. The back surfaces of selected source/drain regions of the resulting structure 210 are exposed at the top ends of the cavities 98. In the exemplary portion of the structure shown in FIG. 21C, the back surface of one source/drain region 76-1 is exposed. BDI layers 38, 64C form portions of the side walls of the cavity 98.

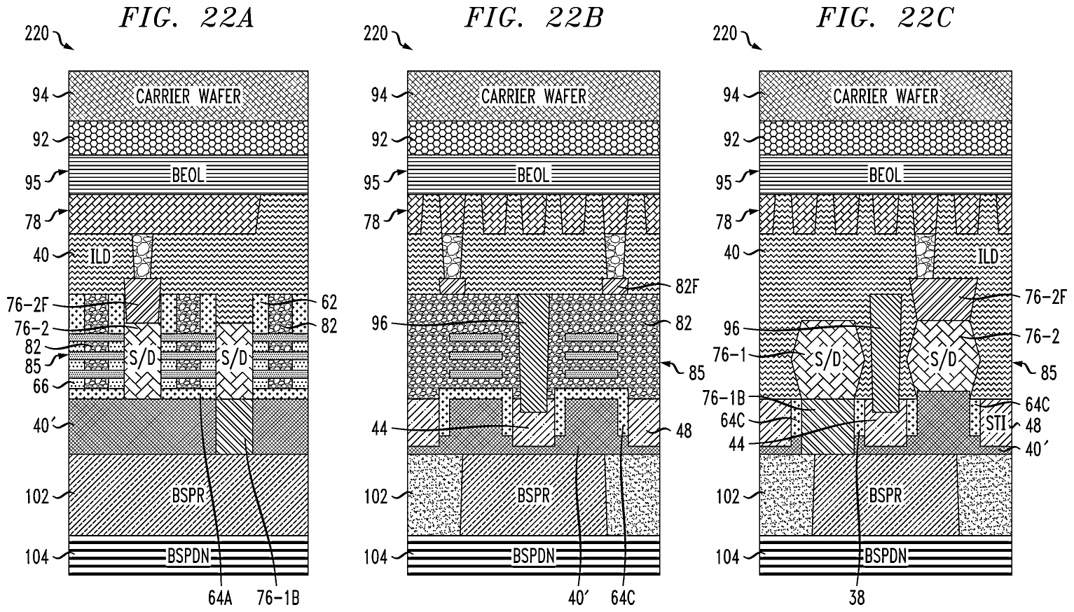

Back side contact metallization is followed by metal overburden removal to form back side source/drain contacts 76-1B. The back side contacts contact the back side (bottom) surfaces of selected source/drain regions 76-1. The back side source/drain contacts may or may not comprise the same metal(s)/metal silicide(s) used to form the front side source/drain contacts. It will be appreciated that the “back side” surfaces are at the top of the structure during back side metallization following wafer flip as discussed above. The back side source/drain contacts extend within the back side ILD layer 40′ and are also bounded by vertically extending BDI layers 38, 64C, as illustrated in FIG. 22C.

Back side interconnect structure(s) are formed over the back side ILD layer 40″. In some embodiments, the back side interconnect structure(s) include a back side power rail (BSPR) 102 and a back side power delivery network (BSPDN) 104. By moving functions such as the power delivery network to the back of a chip, routing jams caused by using just the front side thereof may be avoided. A back side interconnect structure is schematically illustrated in FIG. 22A, FIG. 22B and FIG. 22C. The back side source/drain contacts 76-1B are electrically connected to the back side interconnect structure.

A monolithic semiconductor structure 220 can be obtained using fabrication techniques as discussed above. The structure 220 includes a device layer 85 formed in FEOL processing and has a front side and a back side. Field-effect transistors and possibly other electronic devices (not shown) are incorporated within the device layer. The device layer 85 includes FETs comprising channel regions (stacked silicon nanosheet channel layers 21 in the exemplary structure), source/drain regions 76-1, 76-2 extending laterally from the channel regions, and gate stacks 82, all of which are embedded within an ILD layer 40. A back-end-of-line interconnect layer 95 is positioned over the front side of the device layer 85 and is electrically connected to the field-effect transistors. Front side source/drain contacts 76-1F, 76-2F (shown in FIG. 15D) adjoin the top surfaces of selected source/drain regions. The front side source/drain contacts are employed to electrically connect selected source/drain regions with the BEOL interconnect layer 95. Back side source/drain contacts 76-1B adjoin the back side surfaces of other selected source/drain regions. The back side source/drain contacts are employed to electrically connect selected source/drain regions with the back side interconnect structure. A bottom dielectric layer structure includes a horizontally extending bottom dielectric isolation layer 64A that is located beneath the gate stacks 82 and the channel layers 21. The bottom dielectric layer structure further includes vertically extending BDI layers 38, 64C having upper ends adjoining opposite ends of the horizontally extending BDI layer 64A, as shown in FIG. 22B. The vertically and horizontally extending BDI layers beneath the gate stack 82 adjoin the back side ILD layer 40′. The vertically extending BDI layers 38, 64C further extend between the back side source/drain contact 76-1B and STI regions 44, 48 on opposite sides of the back side source/drain contact, as shown in FIG. 22C.

In some embodiments, a field-effect transistor (or a plurality of FETs) within the device layer 85 includes one source/drain region 76-2 electrically connected by a front side contact to the BEOL layer 95 and another source/drain region 76-1 electrically connected by a back side contact 76-1B to the back side interconnect layers. Some FETs in the device layer 85 may have source/drain regions that are electrically connected only to the BEOL interconnect layer 95 by front side contacts while the source/drain regions of other FETs may be electrically connected only to the back side interconnect layers by back side contacts. In embodiments where the back side interconnect layers comprise signal wires and power wires rather than just power wires, an integrated circuit comprising the FETs may have both source/drain regions of the FETs electrically connected to the back side interconnect layers by back side contacts.

The exemplary fabrication process discussed above allows formation of a bottom dielectric layer structure that includes horizontal as well as vertical portions. During back side silicon recessing, as discussed above with respect to FIG. 16A, FIG. 16B and FIG. 16C and FIG. 17A, FIG. 17B and FIG. 17C, for example, the source/drain regions and the metal gate are protected from damage. Portions of the bottom dielectric layer structure remain beneath the metal gate during and subsequent to silicon recessing. The thin silicon layer between horizontal portions of the bottom dielectric layer structure facilitates source/drain epitaxial growth uniformity as discussed above with respect to FIG. 14C.

One embodiment thus provides a monolithic semiconductor structure, including a device layer having a front side and a back side. The device layer includes a front side interlevel dielectric layer; and a field-effect transistor within the front side interlevel dielectric layer. The field-effect transistor includes a channel region, a gate adjoining the channel region, and first and second source/drain regions extending laterally from the channel region. Also included are a back-end-of-line interconnect layer over the front side of the device layer, the back-end-of-line interconnect layer being electrically connected to the device layer; a back side interlevel dielectric layer over the back side of the device layer; a back side source/drain contact comprising metal, the back side source/drain contact directly contacting a bottom surface of the first source/drain region and extending within the back side interlevel dielectric layer; and a bottom dielectric isolation layer structure comprising a horizontal portion and a pair of vertical portions extending from the horizontal portion, the horizontal portion being between the gate and the back side interlevel dielectric layer, the pair of vertical portions adjoining the back side source/drain contact.

In some cases, such an embodiment can further include a front side source/drain contact comprising metal and directly contacting a top surface of the second source/drain region, the front side source/drain contact being electrically connected to the back-end-of-line interconnect layer; and a back side interconnect layer over the back side of the device layer, the back side source/drain contact being electrically connected to the back side interconnect layer. In some cases, the pair of vertical portions of the bottom dielectric isolation layer structure adjoin the gate and the back side interlevel dielectric layer. In some cases, such an embodiment can even further include shallow trench isolation regions within the back side interlevel dielectric layer, the pair of vertical portions of the bottom dielectric isolation layer structure extending, respectively, between the back side source/drain contact and a pair of the shallow trench isolation regions.

In some cases, the channel region includes a stack of nanosheet semiconductor layers. In some cases, such an embodiment can even further include a gate stack between the nanosheet semiconductor layers, the gate stack comprising the gate, the horizontal portion of the bottom dielectric isolation layer structure adjoining a bottom surface of the gate stack.

In some cases, such an embodiment can still further include a carrier wafer bonded to a top surface of the back-end-of-line interconnect layer.

In some cases, the shallow trench isolation regions extend deeper into the back side interlevel dielectric layer than the pair of vertical portions of the bottom dielectric isolation layer structure.

Another embodiment thus provides a monolithic semiconductor structure including a device layer including a front side and a back side. The device layer includes a front side interlevel dielectric layer; and field-effect transistors within the front side interlevel dielectric layer. Each of the field-effect transistors includes a channel region, a gate adjoining the channel region, and first and second source/drain regions extending laterally from the channel region. Also included are a back-end-of-line interconnect layer over the front side of the device layer, the back-end-of-line interconnect layer being electrically connected to the device layer; a back side interlevel dielectric layer over the back side of the device layer; and back side source/drain contacts comprising metal. Each of the back side source/drain contacts directly contact, respectively, one of the first and second source/drain regions of one of the field-effect transistors and extend within the back side interlevel dielectric layer. Also included are bottom dielectric isolation layer structures comprising, respectively, horizontal portions and pairs of vertical portions extending, respectively, from each of the horizontal portions. Each of the horizontal portions is between the gate of one of the field-effect transistors and the back side interlevel dielectric layer, and each of the pairs of vertical portions adjoins, respectively, one of the back side source/drain contacts.

In some cases, the device layer includes an integrated circuit and the second source/drain regions of a plurality of the field-effect transistors are electrically connected, respectively, to front side source/drain contacts extending within the front side interlevel dielectric layer.

In some cases, each of the pairs of vertical portions of each bottom dielectric isolation layer structure adjoins the gate of one of the field-effect transistors and the back side interlevel dielectric layer.

In some cases, such an embodiment can further include shallow trench isolation regions within the back side interlevel dielectric layer. Each pair of vertical portions of each bottom dielectric isolation layer structure extend, respectively, between the back side source/drain contact of one of the field-effect transistors and a pair of the shallow trench isolation regions.

In some cases, the channel region of each of the field-effect transistors includes a stack of nanosheet semiconductor layers.

In some cases, such an embodiment can further include a gate stack between the nanosheet semiconductor layers of each of the field-effect transistors. The gate stack includes the gate of each field-effect transistor, and the horizontal portion of each bottom dielectric isolation layer structure adjoins a bottom surface of the gate stack of one of the field-effect transistors. In some cases, such an embodiment can still further include a carrier wafer bonded to a top surface of the back-end-of-line interconnect layer.

In some cases, the shallow trench isolation regions extend deeper into the back side interlevel dielectric layer than the pair of vertical portions of each bottom dielectric isolation layer structure.

A further embodiment thus provides a method of fabricating a monolithic semiconductor structure including a back side contact, including obtaining a multi-layer structure. The multi-layer structure includes a semiconductor substrate; shallow trench isolation regions extending within the semiconductor substrate; a first bottom dielectric isolation layer extending horizontally over the semiconductor substrate; a second bottom dielectric isolation layer beneath and extending parallel to the first bottom dielectric isolation layer, a top layer of the semiconductor substrate being between the first bottom dielectric isolation layer and the second bottom dielectric isolation layer, the first dielectric isolation layer including an opening exposing a top surface portion of the top layer of the semiconductor substrate; vertical bottom dielectric isolation layers extending downwardly from the first bottom dielectric isolation layer and the second bottom dielectric isolation layer, each of the vertical bottom dielectric layers adjoining one of the shallow trench isolation regions; stacks of semiconductor channel layers arranged in alternating sequence with sacrificial layers, each of the stacks extending vertically from the first bottom dielectric isolation layer; a sacrificial semiconductor placeholder extending within the semiconductor substrate and between a pair of the vertical bottom dielectric layers, the sacrificial semiconductor placeholder having an exposed top surface; and a sacrificial gate extending across the stacks. The method further includes growing first and second source/drain regions, the first source/drain region being grown on first exposed edge portions of the semiconductor channel layers and on the sacrificial semiconductor placeholder, the second source/drain region being grown on second exposed edge portions of the semiconductor channel layers and on the top surface portion of the top layer of the semiconductor substrate; replacing the sacrificial gate with a metal gate; and replacing the sacrificial placeholder with a back side source/drain contact comprising metal.

In some instances, such a method further includes removing the semiconductor substrate; removing the second bottom dielectric isolation layer; forming a back side interlevel dielectric layer over the shallow trench isolation regions; and forming a back side interconnect structure over the back side interlevel dielectric layer.

In some such instances, such a method still further includes forming a front side interlevel dielectric layer over the first and second source/drain regions and the metal gate; forming a back-end-of-line interconnect layer over the front side interlevel dielectric layer; and bonding a carrier wafer to the back-end-of-line interconnect layer.

In some such instances, such a method even further includes forming a front side contact on the second source/drain contact; and electrically connecting the back-end-of-line interconnect layer with the front side contact.

The drawing figures as discussed above depict exemplary processing steps/stages in the fabrication of exemplary structures. Although the overall fabrication methods and the structures formed thereby are entirely novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example James D. Plummer et al., Silicon VLSI Technology: Fundamentals, Practice, and Modeling 1^{st} Edition, Prentice Hall, 2001, which is hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices or other layers may not be explicitly shown in a given figure for ease of explanation. This does not imply that the semiconductor layer(s) or other layer(s) not explicitly shown are omitted in the actual integrated circuit device.

At least a portion of the techniques described above may be implemented in an integrated circuit. In forming integrated circuits, identical dies are typically fabricated in a repeated pattern on a surface of a semiconductor wafer. Each die includes a device described herein, and may include other structures and/or circuits. The individual dies are cut or diced from the wafer, then packaged as an integrated circuit. One skilled in the art would know how to dice wafers and package die to produce integrated circuits.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from having, for example, FET devices and contacts formed in accordance with one or more of the exemplary embodiments.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this invention. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments may be referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “above” and “below” and “vertical” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.72(b). It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A monolithic semiconductor structure, comprising:
a device layer having a front side and a back side, the device layer comprising:
a front side interlevel dielectric layer; and
a field-effect transistor within the front side interlevel dielectric layer, the field-effect transistor including a channel region, a gate adjoining the channel region, and first and second source/drain regions extending laterally from the channel region;
a back-end-of-line interconnect layer over the front side of the device layer, the back-end-of-line interconnect layer being electrically connected to the device layer;
a back side interlevel dielectric layer over the back side of the device layer;
a back side source/drain contact comprising metal, the back side source/drain contact directly contacting a bottom surface of the first source/drain region and extending within the back side interlevel dielectric layer; and
a bottom dielectric isolation layer structure comprising a horizontal portion and a pair of vertical portions extending from the horizontal portion, the horizontal portion being between the gate and the back side interlevel dielectric layer, the pair of vertical portions adjoining the back side source/drain contact.

2. The monolithic semiconductor structure of claim 1, further including:
a front side source/drain contact comprising metal and directly contacting a top surface of the second source/drain region, the front side source/drain contact being electrically connected to the back-end-of-line interconnect layer; and
a back side interconnect layer over the back side of the device layer, the back side source/drain contact being electrically connected to the back side interconnect layer.

3. The monolithic semiconductor structure of claim 2, wherein the pair of vertical portions of the bottom dielectric isolation layer structure adjoin the gate and the back side interlevel dielectric layer.

4. The monolithic semiconductor structure of claim 3, further including:
shallow trench isolation regions within the back side interlevel dielectric layer, the pair of vertical portions of the bottom dielectric isolation layer structure extending, respectively, between the back side source/drain contact and a pair of the shallow trench isolation regions.

5. The monolithic semiconductor structure of claim 4, wherein the channel region comprises a stack of nanosheet semiconductor layers.

6. The monolithic semiconductor structure of claim 5, further including:
a gate stack between the nanosheet semiconductor layers, the gate stack comprising the gate, the horizontal portion of the bottom dielectric isolation layer structure adjoining a bottom surface of the gate stack.

7. The monolithic semiconductor structure of claim 6, further including a carrier wafer bonded to a top surface of the back-end-of-line interconnect layer.

8. The monolithic semiconductor structure of claim 6, wherein the shallow trench isolation regions extend deeper into the back side interlevel dielectric layer than the pair of vertical portions of the bottom dielectric isolation layer structure.

9. A monolithic semiconductor structure, comprising:
a device layer including a front side and a back side, the device layer comprising:
a front side interlevel dielectric layer; and
field-effect transistors within the front side interlevel dielectric layer, each of the field-effect transistors including a channel region, a gate adjoining the channel region, and first and second source/drain regions extending laterally from the channel region;
a back-end-of-line interconnect layer over the front side of the device layer, the back-end-of-line interconnect layer being electrically connected to the device layer;
a back side interlevel dielectric layer over the back side of the device layer;
back side source/drain contacts comprising metal, each of the back side source/drain contacts directly contacting, respectively, one of the first and second source/drain regions of one of the field-effect transistors and extending within the back side interlevel dielectric layer; and
bottom dielectric isolation layer structures comprising, respectively, horizontal portions and pairs of vertical portions extending, respectively, from each of the horizontal portions, each of the horizontal portions being between the gate of one of the field-effect transistors and the back side interlevel dielectric layer, each of the pairs of vertical portions adjoining, respectively, one of the back side source/drain contacts.

10. The monolithic semiconductor structure of claim 9, wherein the device layer comprises an integrated circuit and the second source/drain regions of a plurality of the field-effect transistors are electrically connected, respectively, to front side source/drain contacts extending within the front side interlevel dielectric layer.

11. The monolithic semiconductor structure of claim 9, wherein each of the pairs of vertical portions of each bottom dielectric isolation layer structure adjoins the gate of one of the field-effect transistors and the back side interlevel dielectric layer.

12. The monolithic semiconductor structure of claim 11, further including:
shallow trench isolation regions within the back side interlevel dielectric layer, each pair of vertical portions of each bottom dielectric isolation layer structure extending, respectively, between the back side source/drain contact of one of the field-effect transistors and a pair of the shallow trench isolation regions.

13. The monolithic semiconductor structure of claim 12, wherein the channel region of each of the field-effect transistors comprises a stack of nanosheet semiconductor layers.

14. The monolithic semiconductor structure of claim 13, further including:
a gate stack between the nanosheet semiconductor layers of each of the field-effect transistors, the gate stack comprising the gate of each field-effect transistor, the horizontal portion of each bottom dielectric isolation layer structure adjoining a bottom surface of the gate stack of one of the field-effect transistors.

15. The monolithic semiconductor structure of claim 14, further including a carrier wafer bonded to a top surface of the back-end-of-line interconnect layer.

16. The monolithic semiconductor structure of claim 14, wherein the shallow trench isolation regions extend deeper into the back side interlevel dielectric layer than the pair of vertical portions of each bottom dielectric isolation layer structure.

17. A method of fabricating a monolithic semiconductor structure including a back side contact, comprising:
obtaining a multi-layer structure including:
a semiconductor substrate;
shallow trench isolation regions extending within the semiconductor substrate;
a first bottom dielectric isolation layer extending horizontally over the semiconductor substrate;
a second bottom dielectric isolation layer beneath and extending parallel to the first bottom dielectric isolation layer, a top layer of the semiconductor substrate being between the first bottom dielectric isolation layer and the second bottom dielectric isolation layer, the first dielectric isolation layer including an opening exposing a top surface portion of the top layer of the semiconductor substrate;
vertical bottom dielectric isolation layers extending downwardly from the first bottom dielectric isolation layer and the second bottom dielectric isolation layer, each of the vertical bottom dielectric layers adjoining one of the shallow trench isolation regions;
stacks of semiconductor channel layers arranged in alternating sequence with sacrificial layers, each of the stacks extending vertically from the first bottom dielectric isolation layer;
a sacrificial semiconductor placeholder extending within the semiconductor substrate and between a pair of the vertical bottom dielectric layers, the sacrificial semiconductor placeholder having an exposed top surface; and
a sacrificial gate extending across the stacks;
growing first and second source/drain regions, the first source/drain region being grown on first exposed edge portions of the semiconductor channel layers and on the sacrificial semiconductor placeholder, the second source/drain region being grown on second exposed edge portions of the semiconductor channel layers and on the top surface portion of the top layer of the semiconductor substrate;
replacing the sacrificial gate with a metal gate; and
replacing the sacrificial placeholder with a back side source/drain contact comprising metal.

18. The method of claim 17, further including removing the semiconductor substrate;
removing the second bottom dielectric isolation layer;
forming a back side interlevel dielectric layer over the shallow trench isolation regions; and
forming a back side interconnect structure over the back side interlevel dielectric layer.

19. The method of claim 18, further including:
forming a front side interlevel dielectric layer over the first and second source/drain regions and the metal gate;
forming a back-end-of-line interconnect layer over the front side interlevel dielectric layer; and
bonding a carrier wafer to the back-end-of-line interconnect layer.

20. The method of claim 19, further including:
forming a front side contact on the second source/drain contact; and
electrically connecting the back-end-of-line interconnect layer with the front side contact.
